(19) United States
(12) Patent Application Publication
(10) Pub. No.: US 2003/0128613 A1
(43) Pub. Date: Jul. 10, 2003

(54) Semiconductor memory device capable of measuring a period of an internally produced periodic signal

(75) Inventor: Takuya Ariki, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/190,669

(22) Filed: Jul. 9, 2002

(30) Foreign Application Priority Data
Jan. 8, 2002 (JP) 2002-001693(P)

(51) Int. Cl. G11C 7/00

(52) U.S. Cl. 365/222

(57) ABSTRACT

A semiconductor memory device includes a period measuring circuit. The period measuring circuit receives a pulse signal sent from a self-timer and a clock signal sent from an external pin. The period measuring circuit counts components of the clock signal existing between two neighboring components of the pulse signal, and issues a count value to an output circuit. The output circuit sends the count value to an I/O terminal. Consequently, the period of the periodic signal issued from the timer circuit can be accurately measured.

### BACKGROUND OF THE INVENTION

1. Field of the Invention

The present invention relates to a semiconductor memory device performing input and output of data in synchronization with a reference periodic signal, and particularly to a semiconductor memory device internally provided with a circuit for measuring a period of an internally produced periodic signal.

2. Description of the Background Art

An SDRAM (Synchronous Dynamic Random Access Memory), which is a kind of conventional semiconductor memory device, is internally provided with a timer circuit which generates a periodic signal having a constant period. The SDRAM performs input/output of data in synchronization with a reference periodic signal (CLK), which is externally input. Since SDRAM is a volatile semiconductor memory, a refresh operation must be performed in accordance with predetermined timing. The timing of the refreshing performed in a self-refresh operation, which is a kind of function of the SDRAM, is determined based on the periodic signal issued from the timer circuit.

Accordingly, the periodic signal is one of very important parameters affecting an operation current and others, which determine the refresh operation timing in the SDRAM.

Before shipment of the semiconductor memory devices such as SDRAMs, therefore, it is necessary to adjust or tune the internal timer circuit to issue the periodic signal having a period of a predetermined value.

For measuring the period of the periodic signal, Japanese Patent Laying-Open No. 9-171682 has disclosed such a manner that a binary counter counts a periodic signal issued during a predetermined time, and the period of the periodic signal is measured based on the count value of the counter and the time, during which the counted periodic signal was issued. Referring to FIG. 16, the counter is reset at a time t1. Then, the counter counts components S1, . . . , Sn−1 and Sn (n: natural number) of the periodic signal issued from an oscillator, and stops the counting at a time t2. A time T between times t1 and t2 is divided by a count value, which was obtained by the counting during time T, to determine a period T0 of the periodic signal.

Further, an operation current of the SDRAM increases during the refresh operation. By utilizing this, the current during the refresh operation is monitored by an oscilloscope with a current probe or the like, and thereby the interval between the refresh operations is determined. Since the refresh operation is performed in accordance with timing synchronized with the periodic signal, the interval thus determined is used as the period of the periodic signal.

In the conventional manner of determining the period of the periodic signal, it is difficult to determine the period with sufficient accuracy because the period of the periodic signal is determined by detecting the interval between times, at which the operation current increases in the refresh operation, by the oscilloscope with the current probe or the like.

In the method disclosed in the Japanese Patent Laying-Open No. 9-171682, the periodic signal itself is counted for determining the period. Therefore, it is difficult to determine the period with high accuracy. More specifically, the start and end of time T, during which the count operation is performed, may not be synchronized with components of the periodic signal. Therefore, the method of obtaining the period by dividing time T of the count operation by the count value cannot accurately determine the period.

### SUMMARY OF THE INVENTION

Accordingly, an object of the invention is to provide a semiconductor memory device internally provided with a circuit, which can accurately measure a period of a periodic signal issued from a timer circuit.

According to the invention, a semiconductor memory device for performing input/output of data into and from memory cells in synchronization with a reference periodic signal, and performing a refresh operation for the memory cells in synchronization with a periodic signal, includes a plurality of memory cells, a periodic signal generating circuit generating the periodic signal, a peripheral circuit performing the input/output of the data into and from each of the plurality of memory cells in synchronization with the reference periodic signal, and performing the refresh operation in synchronization with the periodic signal sent from the periodic signal generating circuit, and a period measuring circuit measuring the period of the periodic signal by using the reference periodic signal having a second period shorter than a first period of the periodic signal.

The period of the periodic signal is measured with the signal having a shorter period than the periodic signal. According to the invention, therefore, the period of the periodic signal internally produced from the semiconductor memory device can be accurately measured.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic block diagram of a semiconductor memory device according to a first embodiment of the invention;

FIG. 2 is a circuit diagram of a period measuring circuit shown in FIG. 1;

FIG. 3 is a signal timing chart for representing an operation of the period measuring circuit shown in FIG. 2;

FIG. 4 is a circuit diagram of an output circuit shown in FIG. 1;

FIG. 5 is a schematic block diagram of a semiconductor memory device according to a second embodiment of the invention;

FIG. 6 is a circuit diagram of a period measuring circuit shown in FIG. 5;

FIG. 7 is a signal timing chart for representing an operation of the period measuring circuit shown in FIG. 6;

FIG. 8 is a schematic block diagram of a semiconductor memory device according to a third embodiment;

FIG. 9 is a circuit diagram of a period measuring circuit shown in FIG. 8;

FIG. 10 is a signal timing chart for representing an operation of the period measuring circuit shown in FIG. 9;

FIG. 11 is a schematic block diagram of a semiconductor memory device according to a fourth embodiment of the invention;

FIG. 12 is a circuit diagram of a period measuring circuit shown in FIG. 11;

FIG. 13 is a signal timing chart for representing an operation of the period measuring circuit shown in FIG. 12;

FIG. 14 is a schematic block diagram of a semiconductor memory device according to a fifth embodiment;

FIG. 15 is a circuit diagram of a period measuring circuit shown in FIG. 14; and

FIG. 16 is a signal timing chart for representing a conventional method of measuring a period of a periodic signal.

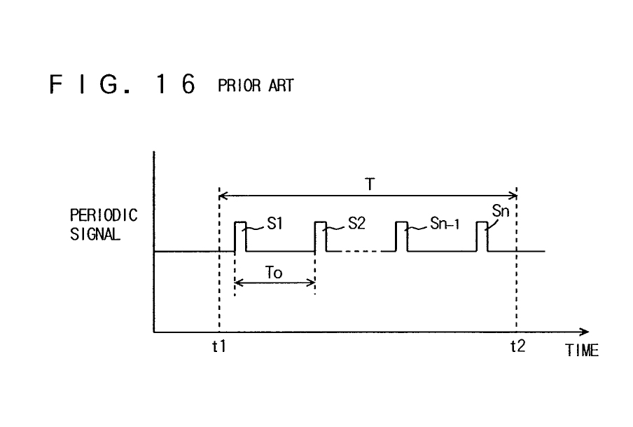

### DESCRIPTION OF THE PREFERRED EMBODIMENTS

Embodiments of the invention will now be described with reference to the drawings. In the figures, the same or corresponding portions bear the same reference numbers, and description thereof is not repeated.

[First Embodiment]

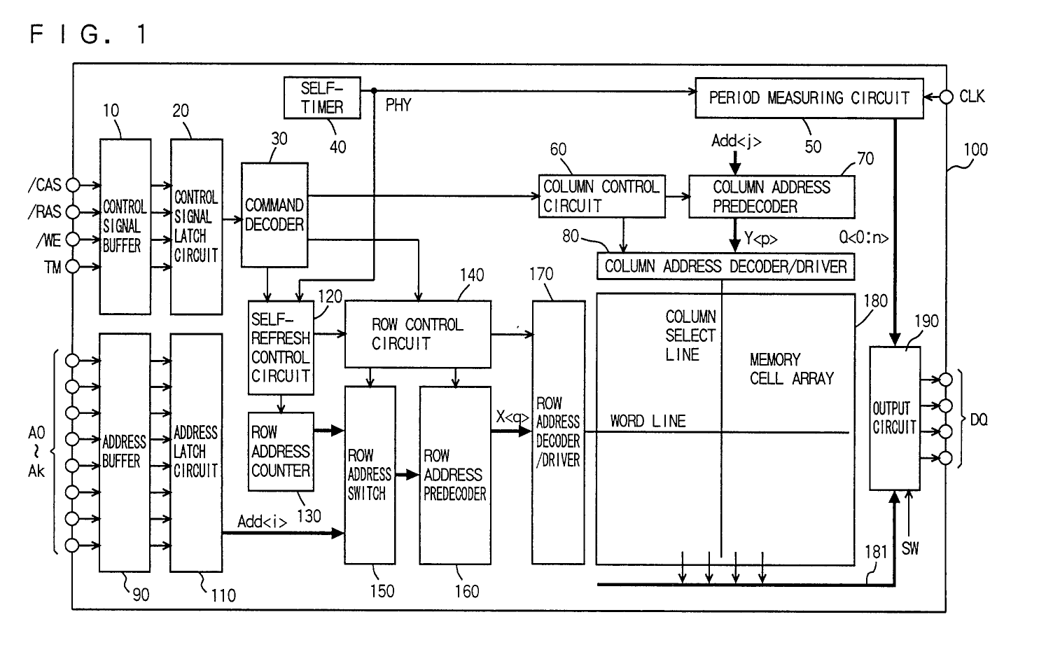

Referring to FIG. 1, a semiconductor memory device 100 of a first embodiment of the invention includes a control signal buffer 10, a control signal latch circuit 20, a command decoder 30, a self-timer 40, a period measuring circuit 50, a column control circuit 60, a column address predecoder 70, a column address decoder/driver 80, an address buffer 90, an address latch circuit 110, a self-refresh control circuit 120, a row address counter 130, a row control circuit 140, a row address switch 150, a row address predecoder 160, a row address decoder/driver 170, a memory cell array 180, a data bus 181 and an output circuit 190.

Control signal buffer 10 buffers control signals such as a column address strobe signal/CAS, a row address strobe signal/RAS, a write enable signal/WE and a test mode signal TM, which are input from control signal pins, and sends the control signals such as column address strobe signal/CAS thus buffered to control signal latch circuit 20. Test mode signal TM is a signal for placing semiconductor memory device 100 in a test mode. Usually, semiconductor memory device 100 enters the test mode when combinations of logical levels of the control signals such as column address strobe signal/CAS and logical levels of the address exhibit a predetermined state. According to the invention, combinations of the logical levels of the control signals and address, which place semiconductor memory device 100 in the test mode, are collectively handled as test mode signal TM.

Control signal latch circuit 20 latches the control signals such as column address strobe signal/CAS, which are received from control signal buffer 10, and sends the latched control signals such as column address strobe signal/CAS to command decoder 30.

Command decoder 30 decodes the control signals such as column address strobe signal/CAS received from control signal latch circuit 20. Command decoder 30 sends various command signals thus decoded to appropriate control circuit groups. Command decoder 30 issues a switch signal SW at H-level to output circuit 190 when test mode signal TM at H level is input. When test mode signal TM at L-level is input, command decoder 30 issues switch signal SW at L-level to output circuit 190. In FIG. 1, a signal line between command decoder 30 and output circuit 190 is not shown for the sake of simplicity.

Self-timer 40 is formed of a ring oscillator. Self-timer 40 produces a pulse signal PHY having a constant period, and sends pulse signal PHY thus generated to period measuring circuit 50 and self-refresh control circuit 120.

Period measuring circuit 50 receives pulse signal PHY issued from self-timer 40 and clock signal CLK sent from an external pin, and counts components of clock signal CLK, which are present between neighboring two components of pulse signal PHY, in a manner to be described later. Period measuring circuit 50 outputs results of the counting as a count value Q<0:n> of n (n: natural number) bits to output circuit 190.

Address buffer 90 buffers address signals A0-Ak (k: natural number) sent from address pins, and sends address signals A0-Ak thus buffered to address latch circuit 110.

Address latch circuit 110 latches address signals A0-Ak sent from address buffer 90, and sends address signals A0-Ak thus latched as a column address Add<j> (j: natural number) to column address predecoder 70. Also, address latch circuit 110 outputs address signals A0-Ak as a row address Add<i> (i: natural number) to row address switch 150.

When self-refresh control circuit 120 receives a self-refresh activating signal from command decoder 30, self-refresh control circuit 120 activates row address counter 130 in synchronization with pulse signal PHY sent from self-timer 40, and issues an instructing signal for performing self-refresh of memory cells included in memory cell array 180 to row control circuit 140.

When row address counter 130 is activated by self-refresh control circuit 120, it counts the row address, and sends the counted row address to row address switch 150. Thus, row address counter 130 issues the row address to row address switch 150 when the memory cells are to be self-refreshed.

Row control circuit 140 controls row address switch 150 to select row address Add<i> sent from address latch circuit 110 based on the command signal sent from command decoder 30. When an instructing signal for instructing the refresh operation is input from self-refresh control circuit 120, row control circuit 140 controls row address switch 150 to select the row address sent from row address counter 130. Row control circuit 140 activates row address predecoder 160 and row address decoder/driver 170.

Row address switch 150 selects row address Add<i> sent from address latch circuit 110 or the row address sent from row address counter 130 under the control of row control circuit 140, and sends the selected row address to row address predecoder 160.

When row address predecoder 160 is activated by row control circuit 140, it predecodes the row address sent from row address switch 150, and sends predecoded row address X<q> (q: natural number) to row address decoder/driver 170.

When row address decoder/driver 170 is activated by row control circuit 140, it decodes row address X<q> sent from row address predecoder 160 to activate the word line designated by the decoded row address.

Column control circuit 60 activates column address predecoder 70 and column address decoder/driver 80 based on the command signal sent from command decoder 30.

When column address predecoder 70 is activated by column control circuit 60, it predecodes column address Add<j> (j: natural number) sent from address latch circuit 110, and sends a predecoded column address Y<p> (p: natural number) to column address decoder/driver 80.

When column address decoder/driver 80 is activated by column control circuit 60, it decodes column address Y<p> sent from column address predecoder 70, and activates the column select line designated by decoded column address Y<p>.

Memory cell array 180 includes a plurality of memory cells arranged in r rows and s columns (r and s: natural numbers), r column select lines, s word lines, r bit line pairs BLr and /BLr provided corresponding to the r column select lines, respectively, r sense amplifiers provided corresponding to the r column select lines, respectively, and r equalize circuits provided corresponding to the r column select lines, respectively.

Data bus 181 sends the read data, which is output from memory cell array 180, to output circuit 190.

Output circuit 190 selects count value Q<0:n> sent from period measuring circuit 50 or the read data sent from data bus 181 based on a switch signal SW sent from command decoder 30, and outputs selected count value Q<0:n> or the read data to I/O terminal DQ.

Control signal buffer 10, control signal latch circuit 20, command decoder 30, column control circuit 60, column address predecoder 70, column address decoder/driver 80, address buffer 90, address latch circuit 110, row control circuit 140, row address switch 150, row address predecoder 160 and row address decoder/driver 170 form “peripheral circuits” for performing input/output of data into or from the memory cells included in memory cell array 180 and performing self-refreshing of the memory cells.

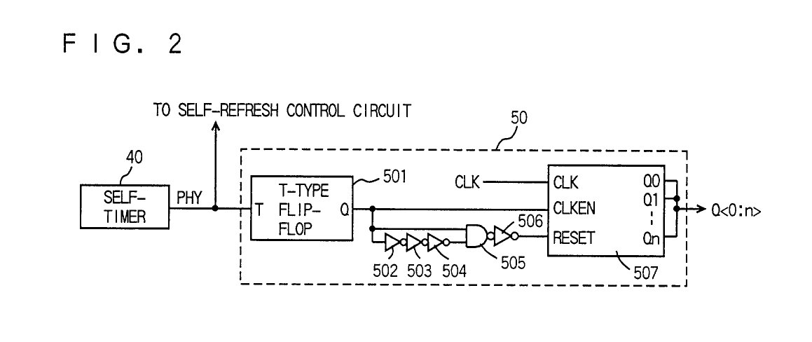

Referring to FIG. 2, period measuring circuit 50 includes a T-type flip-flop 501, inverters 502, 503, 504 and 506, a NAND gate 505 and a binary counter 507.

T-type flip-flop 501 receives pulse signal PHY sent from self-timer 40, and outputs a signal Qp having a logical level, which changes in synchronization with the rising of the logical level of received pulse signal PHY, based on pulse signal PHY.

Inverters 502-504 delay signal Qp sent from T-type flip-flop 501 by a predetermined time, and output the delay signal to a terminal of NAND gate 505.

NAND gate 505 receives signal Qp from T-type flip-flop 501 on one of its terminals, and also receives the foregoing output signal of inverter 504 on the other terminal. NAND gate 505 performs logical AND between the received two signals, and inverts results of the logical AND to send the inverted result to inverter 506. Inverter 506 inverts the output signal of NAND gate 505, and outputs the inverted signal to binary counter 507 as a reset signal.

Inverters 502-504 and 506 as well as NAND gate 505 form a reset signal generating circuit for generating the reset signal based on signal Qp sent from T-type flip-flop 501.

Binary counter 507 receives clock signal CLK sent from an external pin on its CLK terminal, receives signal Qp sent from T-type flip-flop 501 on its CLKEN terminal and receives the reset signal sent from inverter 506 on its RESET terminal. Binary counter 507 counts components of clock signal CLK received on its CLK terminal when signal Qp received on the CLKEN terminal is at H-level, and outputs the results of counting as count value Q<0:n>. Binary counter 507 resets count value Q<0:n> when the reset signal received on the RESET terminal attains H-level.

In the above description, the inverters employed for generating the reset signal are three in number. However, the number is not restricted to three, and odd inverters other than three may be employed.

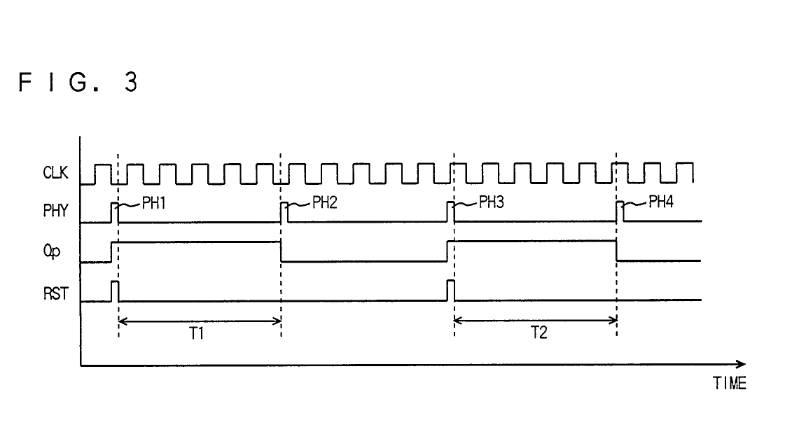

Referring to FIG. 3, description will now be given on an operation of period measuring circuit 50. When self-timer 40 outputs pulse signal PHY, T-type flip-flop 501 receives pulse signal PHY, and sends signal Qp, of which logical level changes in accordance with the change of the logical level of pulse signal PHY from L-level to H-level, i.e., in synchronization with the rising. The reset signal generating circuit formed of inverters 502-504 and 506 and NAND gate 505 produces a reset signal RST synchronized with the rising of signal Qp based on signal Qp sent from T-type flip-flop 501.

Binary counter 507 is reset when it receives reset signal RST in synchronization with the rising of signal Qp. Thereafter, binary counter 507 counts the components of clock signal CLK sent through CLK terminal while signal Qp is at H-level, outputs a result of this counting as count value Q<0:n>.

In this case, signal Qp holds H-level for a duration from rising of a component PH1 of pulse signal PHY to rising of a component PH2, or for a duration from rising of a component PH3 to rising of a component PH4. Binary counter 507 stops the counting operation and resets the count value when reset signal RST is at H-level. Therefore, binary counter 507 counts the components of clock signal CLK for a duration T1 (or T2) determined by subtracting the duration of H-level of reset signal RST from the duration of H-level of signal Qp. Thus, binary counter 507 counts the components of clock signal CLK, which exist between the neighboring two components of pulse signal PHY (i.e., between components PH1 and PH2, or between components PH3 and PH4). Signal Qp at H-level is referred to as a “detection window signal”.

Since clock signal CLK sent from the external pin has a period, which is already known, the period of pulse signal PHY can be determined by multiplying count value Q<0:n> output from I/O terminal DQ by the period of clock signal CLK. Therefore, the counting of components of clock signal CLK existing between the neighboring two components of pulse signal PHY corresponds to the measuring of the period of pulse signal PHY.

As described above, the invention has such a distinctive feature that the period of pulse signal PHY is measured by counting the components of clock signal CLK having a shorter period than pulse signal PHY. This feature of the invention allows accurate measuring of the period of pulse signal PHY.

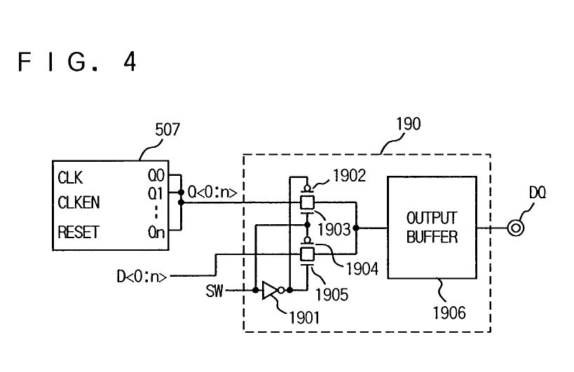

Referring to FIG. 4, output circuit 190 includes an inverter 1901, P-channel MOS transistors 1902 and 1904, N-channel MOS transistors 1903 and 1905, and an output buffer 1906.

Inverter 1901 inverts switch signal SW sent from command decoder 30, and applies it to gate terminals of P- and N-channel MOS transistors 1902 and 1905. P-channel MOS transistor 1902 receives the output signal of inverter 1901 on its gate terminal. N-channel MOS transistor 1903 receives switch signal SW sent from command decoder 30 on its gate terminal. P-channel MOS transistor 1902 has a source terminal connected to a source terminal of N-channel MOS transistor 1903, and has a drain terminal connected to a drain terminal of N-channel MOS transistor 1903. P- and N-channel MOS transistors 1902 and 1903 form a transfer gate. P- and N-channel MOS transistors 1902 and 1903 receive count value Q<0:n> of binary counter 507 on their source terminals, and send count value Q<0:n> to output buffer 1906 when output circuit 190 receives switch signal SW at H-level from command decoder 30.

P-channel MOS transistor 1904 receives switch signal SW from command decoder 30 on its gate terminal. N-channel MOS transistor 1905 receives the output signal of inverter 1901 on its gate terminal. P-channel MOS transistor 1904 has a source terminal connected to a source terminal of N-channel MOS transistor 1905, and has a drain terminal connected to a drain terminal of N-channel MOS transistor 1905. P- and N-channel MOS transistors 1904 and 1905 form a transfer gate. P- and N-channel MOS transistors 1904 and 1905 receive read data D<0:n> sent from data bus 181 on their source terminals, and send read data D<0:n> to output buffer 1906 when output circuit 190 receives switch signal SW at L-level from command decoder 30. Output buffer 1906 buffers count value Q<0:n> or read data D<0:n>, and sends buffered count value Q<0:n> or buffered read data D<0:n> to I/O terminal DQ.

When semiconductor memory device 100 is to be placed in the test mode, test mode signal TM at H-level is sent to semiconductor memory device 100 so that command decoder 30 produces switch signal SW at H-level based on test mode signal TM at H-level, and sends it to output circuit 190. In output circuit 190, P- and N-channel MOS transistors 1902 and 1903 are turned on, and P- and N-channel MOS transistors 1904 and 1905 are turned off based on switch signal SW at H-level. As a result, count value Q<0:n> sent from binary counter 507 is sent to output buffer 1906 via P- and N-channel MOS transistors 1902 and 1903, and is sent from output buffer 1906 to I/O terminal DQ.

In a normal operation, test mode signal TM at L-level is sent to semiconductor memory device 100. Therefore, command decoder 30 produces switch signal SW at L-level based on test mode signal TM at L-level, and sends it to output circuit 190. In output circuit 190, P- and N-channel MOS transistors 1902 and 1903 are turned off, and P- and N-channel MOS transistors 1904 and 1905 are turned on based on switch signal SW at L-level. Consequently, read data D<0:n> on data bus 181 is sent to output buffer 1906 via P- and N-channel MOS transistors 1904 and 1905, and is sent from output buffer 1906 to I/O terminal DQ.

As described above, output circuit 190 applies count value Q<0:n> output from binary counter 507 to I/O terminal DQ when semiconductor memory device 100 enters the test mode. In the normal operation of semiconductor memory device 100, output circuit 190 outputs read data D<0:n> read from the memory cells to I/O terminal DQ.

Referring to FIG. 1 again, description will now be given on various operations in semiconductor memory device 100. For writing data into the memory cell included in memory cell array 180, semiconductor memory device 100 is supplied with column address strobe signal/CAS at L-level, row address strobe signal/RAS at L-level, write enable signal/WE at L-level and test mode signal TM at L-level. Thereby, control signal buffer 10 buffers the control signals such as column address strobe signal/CAS, and sends the buffered control signals such as column address strobe signal/CAS to control signal latch circuit 20. Control signal latch circuit 20 latches the control signals such as column address strobe signal/CAS, and sends the latched control signals such as column address strobe signal/CAS to command decoder 30.

Command decoder 30 decodes the control signals such as column address strobe signal/CAS, and sends various portions of the decoder signals to column control circuit 60, row control circuit 140, an input circuit (not shown), output circuit 190 and self-refresh control circuit 120, respectively. Command decoder 30 produces switch signal SW at L-level based on test mode signal TM at L-level, and sends produced switch signal SW to output circuit 190.

Address buffer 90 buffers received address signals A0-Ak, and sends buffered address signals A0-Ak to address latch circuit 110. Address latch circuit 110 sends received address signals A0-Ak as column address Add<j> and row address Add<i> to column address predecoder 70 and row address switch 150, respectively.

Thereby, self-refresh control circuit 120 receives a command signal and pulse signal PHY, and issues an instructing signal for not performing the self-refreshing of the memory cell to row control circuit 140 in synchronization with pulse signal PHY so that row address counter 130 becomes inactive. Row control circuit 140 receives the command signal from command decoder 30 so that it activates row address predecoder 160 and row address decoder/driver 170. Also, row control circuit 140 receives the instructing signal from self-refresh control circuit 120, and controls row address switch 150 to select row address Add<i> sent from address latch circuit 110.

Row address switch 150 selects row address Add<i> sent from address latch circuit 110 under the control of row control circuit 140, and sends selected row address Add<i> to row address predecoder 160. Row address predecoder 160 predecodes row address Add<i>, and sends a predecoded row address X<q> to row address decoder/driver 170. Row address decoder/driver 170 decodes row address X<q>, and activates the word line designated by the row address thus decoded.

When column control circuit 60 receives the command signal from command decoder 30, it activates column address predecoder 70 and column address decoder/driver 80.

Column address predecoder 70 predecodes received column address Add<j>, and sends predecoded column address Y<p> to column address decoder/driver 80. Column address decoder/driver 80 decodes column address Y<p>, and activates the column select line designated by the decoded column address. The write data sent from I/O terminal DQ is applied to data bus 181 via an input circuit (not shown), and is written via data bus 181 to the memory cell designated by the active column select line and the active word line. Thereby, the operation of writing data into the memory cell is completed.

In this case, command decoder 30 sends a command signal for not outputting a signal to output circuit 190 so that output buffer 1906 included in output circuit 190 becomes inactive. Therefore, output circuit 190 does not output data to I/O terminal DQ. Period measuring circuit 50 counts clock signal CLK sent from the external pin based on pulse signal PHY sent from self-timer 40 and clock signal CLK as already described, and sends count value Q<0:n> to output circuit 190. However, output buffer 1906 is inactive as already described so that count value Q<0:n> is not sent to I/O terminal DQ.

Description will now be given on operations of semiconductor memory device 100 for reading the data from the memory cell. Semiconductor memory device 100 receives column address strobe signal/CAS at L-level, row address strobe signal/RAS at L-level, write enable signal/WE at H-level and test mode signal TM at L-level, and the column select line designated by the column address and the word line designated by the row address are activated by the same operations as those already described. In this case, command decoder 30 produces switch signal SW at L-level based on test mode signal TM at L-level, and sends switch signal SW at L-level thus produced to output circuit 190. Since command decoder 30 sends to output circuit 190 the command signal for outputting the signal, output buffer 1906 becomes active.

Read data, which is read from the memory cell designated by the active column select line and the active word line, is sent to data bus 181 via the bit line pair and the sense amplifier, and is sent from data bus 181 to output circuit 190. In output circuit 190, read data D<0:n> is sent to output buffer 1906 based on switch signal SW at L-level sent from command decoder 30, and output buffer 1906 outputs read data D<0:n> to I/O terminal DQ. Thereby, the read data read out from the memory cell is sent to I/O terminal DQ. In this case, period measuring circuit 50 sends count value Q<0:n> to output circuit 190 similarly to the foregoing case. In output circuit 190, however, P- and N-channel MOS transistors 1902 and 1903 are turned off based on switch signal SW at L-level so that count value Q<0:n> is not output to I/O terminal DQ.

Description will now be given on the operations for performing the self-refresh in semiconductor memory device 100. In this case, semiconductor memory device 100 receives the self-refresh activating signal formed of a predetermined combination of the logical levels. Thereby, control signal buffer 10, control signal latch circuit 20 and command decoder 30 perform the same operations as those already described. Column control circuit 60 deactivates column address predecoder 70 and column address decoder/driver 80 based on the command signal.

Self-refresh control circuit 120 receives the self-refresh activating signal sent from command decoder 30 and pulse signal PHY sent from self-timer 40, and activates row address counter 130 in synchronization with pulse signal PHY. Also, self-refresh control circuit 120 sends the instructing signal for performing the self-refresh to row control circuit 140 in synchronization with pulse signal PHY.

Thereby, row control circuit 140 activates row address predecoder 160 and row address decoder/driver 170 based on the command signal, and controls row address switch 150 to select the row address sent from the row address counter 130 based on the instructing signal sent from self-refresh control circuit 120.

Row address counter 130 counts the row address, and sends the counted row address to row address switch 150. Row address switch 150 selects the row address sent from row address counter 130 under the control of row control circuit 140, and sends the selected row address to row address predecoder 160. Thereafter, the word line designated by the row address is activated by the operations already described, and the refresh operation is performed. In this case, output circuit 190 and the input circuit (not shown) are inactive so that input/output of data with respect to semiconductor memory device 100 does not occur.

For placing semiconductor memory device 100 in the test mode, semiconductor memory device 100 is supplied with test mode signal TM at H-level. In the present invention, the test mode means a mode, in which the period of pulse signal PHY sent from self-timer 40 is measured, and results of the measurement are sent to I/O terminal DQ. Thus, the test mode does not mean a mode, in which a test is performed by inputting and/or outputting data into and/or from memory cells.

Accordingly, when test mode signal TM at H-level is input, command decoder 30 produces switch signal SW at H-level based on test mode signal TM at H-level, and sends it to output circuit 190.

Period measuring circuit 50 counts the components of clock signal CLK existing between the neighboring two components of pulse signal PHY, and sends count value Q<0:n> to output circuit 190. In output circuit 190, thereby, count value Q<0:n> is selected based on switch signal SW at H-level, and is sent to I/O terminal DQ via output buffer 1906. Based on count value Q<0:n> thus sent, the period of pulse signal PHY is accurately determined.

Although particular description has not been given, control signal buffer 10, control signal latch circuit 20, command decoder 30, column control circuit 60, column address predecoder 70, column address decoder/driver 80, address buffer 90, address latch circuit 110, row control circuit 140, row address switch 150, row address predecoder 160 and row address decoder/driver 170 operate in synchronization with externally applied clock signal CLK. Thus, input and output of data into and from the memory cells included in memory cell array 180 are performed in synchronization with clock signal CLK.

According to the first embodiment, the semiconductor memory device includes a period measuring circuit, which uses the clock signal having a smaller period than that of the pulse signal sent from the self-timer, and counts the components of the clock signal existing between the neighboring two components of the pulse signal. Therefore, the period of the pulse signal can be determined accurately.

[Second Embodiment]

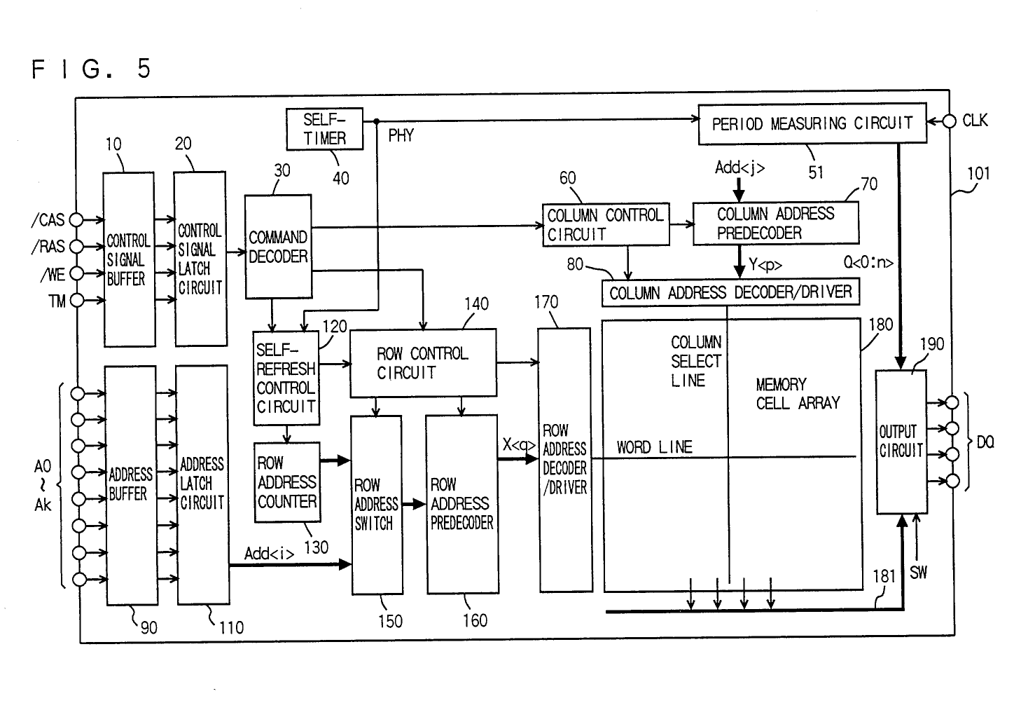

Referring to FIG. 5, a semiconductor memory device 101 according to a second embodiment is the same as semiconductor memory device 100 except for that a period measuring circuit 51 is employed instead of period measuring circuit 50 in semiconductor memory device 100.

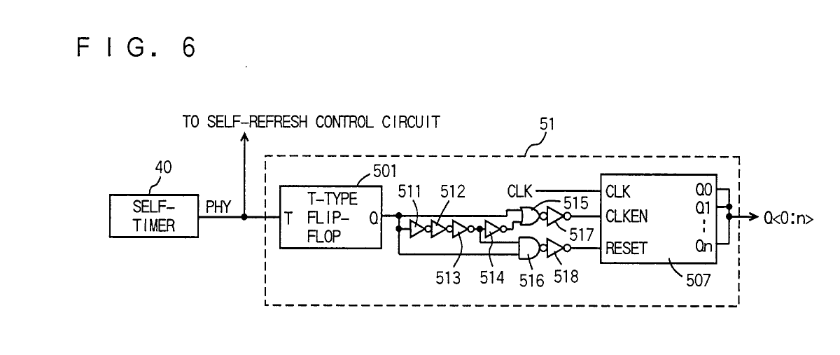

Referring to FIG. 6, period measuring circuit 51 includes T-type flip-flop 501 as well as a binary counter 507, inverters 511-514, 517 and 518, a NOR gate 515 and a NAND gate 516. T-type flip-flop 501 is the same as that already described.

Inverters 511-513 delay signal Qp sent from T-type flip-flop 501 by a predetermined time, and apply it to one of terminals of NAND gate 516. NAND gate 516 receives signal Qp sent from T-type flip-flop 501 on the other terminal, performs logical AND between signal Qp and the output signal of inverter 513, and inverts results of the logical AND to send the inverted result to inverter 518. Inverter 518 inverts the output signal of NAND gate 516, and sends it to the RESET terminal of binary counter 507. Therefore, inverters 511-513 and 518 and NAND gate 516 form a reset signal generating circuit for generating a reset signal.

Inverter 514 inverts the output signal of inverter 513, and sends it to the other terminal of NOR gate 515. NOR gate 515 receives signal Qp sent from T-type flip-flop 501 on its one terminal, performs logical OR between signal Qp and the output signal of inverter 514, and inverts results of the logical OR to send the inverted result to inverter 517. Inverter 517 inverts the output signal of NOR gate 515, and sends it to the CLKEN terminal of binary counter 507.

Binary counter 507 counts clock signal CLK received from an external pin while the signal received from inverter 517 is at H-level, and sends count value Q<0:n> to output circuit 190. When the reset signal received from inverter 518 is at H-level, binary counter 507 stops the count operation, and resets count value Q<0:n>.

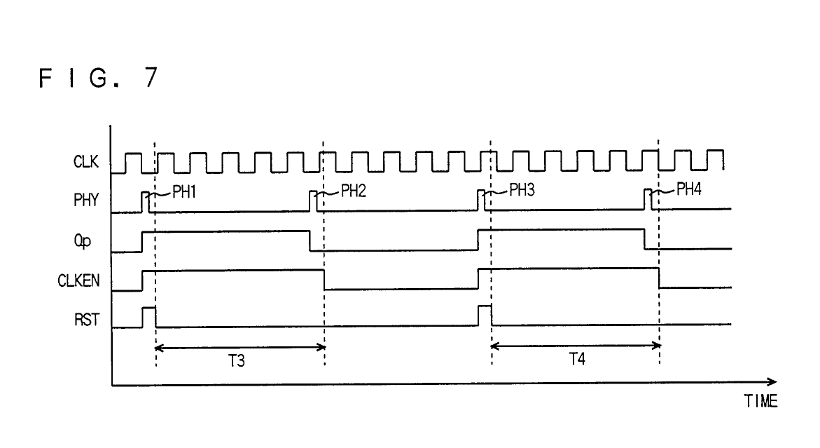

Referring to FIG. 7, description will now be given on operations in period measuring circuit 51. T-type flip-flop 501 produces signal Qp based on pulse signal PHY sent from self-timer 40 as already described, and sends signal Qp thus produced to one of the terminals of NOR gate 515, inverter 511 and the other terminal of NAND gate 516. Inverters 511-513 delay signal Qp by a predetermined time, and sends it to one of the terminals of NAND gate 516. NAND gate 516 performs logical AND between the output signal of inverter 513 and signal Qp, and inverts results of the logical AND to send the inverted result to inverter 518. Inverter 518 inverts the output signal of NAND gate 516 to issue reset signal RST to the RESET terminal of binary counter 507.

Inverter 514 inverts the output signal of inverter 513. NOR gate 515 performs logical AND between the output signal of inverter 514 and signal Qp sent from T-type flip-flop 501, and inverts results of the logical OR to send the inverted result to inverter 517. Inverter 517 inverts the output signal of NOR gate 515 to issue signal CLKEN to the CLKEN terminal of binary counter 507. In this case, NOR gate 515 performs the logical OR between signal Qp and the signal prepared by delaying signal Qp by a predetermined time. Therefore, signal CLKEN maintains H-level for a longer duration than that of H-level of signal Qp, and maintains L-level for a shorter duration than that of L-level of signal Qp.

Thereby, binary counter 507 counts the components of clock signal CLK while signal CLKEN is at H-level and reset signal RST is at L-level, and sends count value Q<0:n> to output circuit 190.

Since inverter 514 inverts signal Qp delayed by three inverters 511-513, NOR gate 515 performing the logical OR produces a signal by extending the duration of H-level of signal Qp by a time equal to the delay time of inverters 511-513. Signal Qp delayed by inverters 511-513 is used for generating reset signal RST, and the delay time of inverters 511-513 corresponds to the duration of H-level of reset signal RST. Therefore, NOR gate 515 performing the logical OR produces the signal by extending the duration of H-level of signal Qp by a time equal to the duration of H-level of reset signal RST. As a result, inverter 517 sends signal CLKEN, which is produced by extending the duration of H-level of signal Qp by a time equal to the duration of H-level of reset signal RST, to the CLKEN terminal of binary counter 507.

Signal Qp holds the H-level for a duration corresponding to the period of pulse signal PHY, and signal CLKEN is produced by extending the duration of H-level of signal Qp by a time equal to the duration of H-level of reset signal RST. Further, binary counter 507 counts the components of clock signal CLK for a duration T3 (or T4), i.e., while signal CLKEN is at H-level and reset signal RST is at L-level. Therefore, binary counter 507 counts the components of clock signal CLK for a duration corresponding to the period of pulse signal PHY. As a result, the duration, for which clock signal CLK cannot be counted due to reset signal RST, can be ensured as the duration for the count operation so that the period of pulse signal PHY can be measured more accurately.

Signal Qp at H-level is referred to as a “preliminary detection window signal”, and signal CLKEN at H-level is referred to as a “detection window signal”. The number of inverters delaying signal Qp by a predetermined time is not restricted to three, and odd inverters other than three may be employed.

Structures and operations other than the above are the same as those of the first embodiment.

According to the second embodiment, the semiconductor memory device includes the period measuring circuit for performing the count operation to issue the count value for a duration corresponding to the period of the pulse signal applied from the timer circuit. Therefore, the period of the pulse signal can be measured more accurately.

[Third Embodiment]

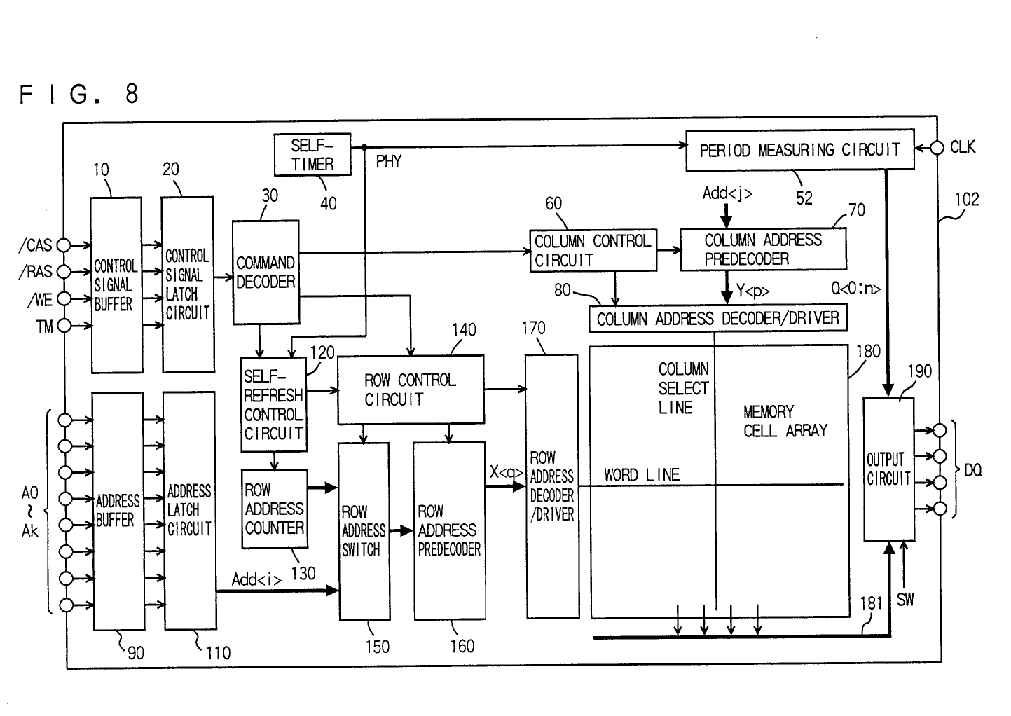

Referring to FIG. 8, a semiconductor memory device 102 of a third embodiment is the same as semiconductor memory device 100 except for that a period measuring circuit 52 is employed instead of period measuring circuit 50.

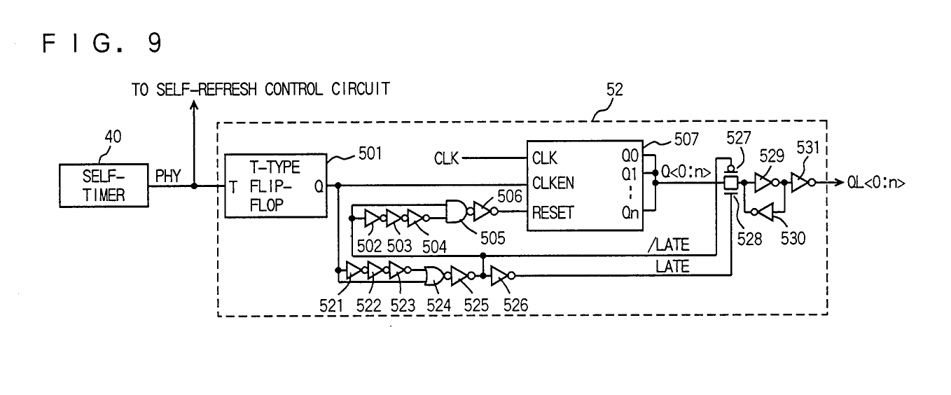

Referring to FIG. 9, period measuring circuit 52 includes T-type flip-flop 501, inverters 502-504, 506, 521-523, 525, 526 and 529-531, NAND gate 505, binary counter 507, a NOR gate 524, a P-channel MOS transistor 527 and an N-channel MOS transistor 528. T-type flip-flop 501 is the same as that already described. Inverters 502-504 and 506 as well as NAND gate 505 form a reset signal generating circuit for generating reset signal RST as already described with reference to the first embodiment.

Inverters 521-523 delay signal Qp sent from T-type flip-flop 501 by a predetermined time, and send it to the other terminal of NOR gate 524. NOR gate 524 receives signal Qp sent from T-type flip-flop 501 on one of the terminals, performs logical OR between signal Qp and the output signal of inverter 523, and inverts results of the logical OR. Inverter 525 inverts the output signal of NOR gate 524, and applies a signal/LATE produced by this inversion to each of inverters 502, 526 and one of terminals of NAND gate 505 as well as a gate terminal of P-channel MOS transistor 527. Inverter 526 inverts signal/LATE to apply a signal LATE to a gate terminal of N-channel MOS transistor 528.

Inverters 502-504 and 506 as well as NAND gate 505 generate reset signal RST based on signal/LATE by the operations already described with reference to FIG. 1, and sends reset signal RST thus produced to the RESET terminal of binary counter 507.

Binary counter 507 counts the components of clock signal CLK, which is received from the external pin, to output count value Q<0:n> while signal Qp sent from T-type flip-flop 501 is at H-level. Binary counter 507 resets count value Q<0:n> while reset signal RST sent from inverter 506 is at H-level.

P-channel MOS transistor 527 has a source terminal connected to a source terminal of N-channel MOS transistor 528 and a drain terminal connected to a drain terminal of N-channel MOS transistor 528. P-channel MOS transistor 527 receives signal/LATE from inverter 525 on its gate terminal, and N-channel MOS transistor 528 receives signal LATE from inverter 526 on its gate terminal. P-channel MOS transistor 527 and N-channel MOS transistor 528 form a transfer gate, and sends count value Q<0:n>, which is output from binary counter 507, to inverter 529 while signal LATE is at H-level (and thus signal/LATE is at L-level).

Inverters 529 and 530 form a latch circuit, which latches count value Q<0:n> sent from P- and N-channel MOS transistors 527 and 528, and output it to inverter 531. Inverter 531 inverts the output signal of the latch circuit to issue count value Q<0:n> to output circuit 190.

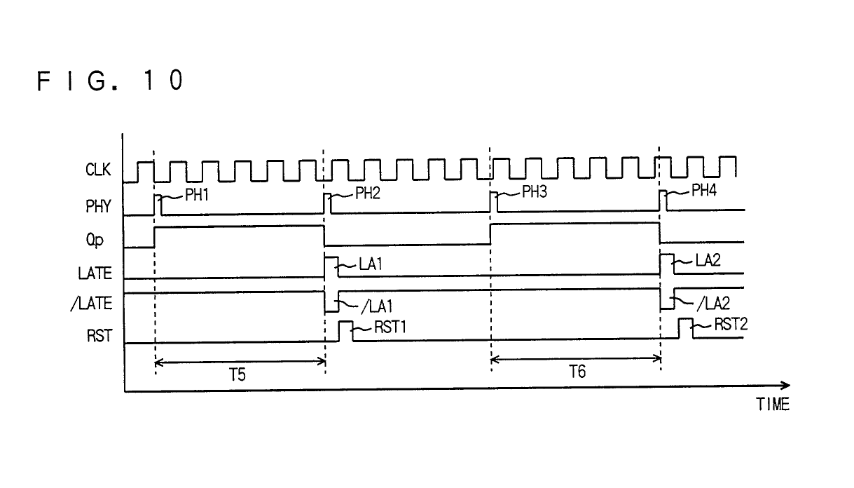

Referring to FIG. 10, description will now be given on operations of period measuring circuit 52.

T-type flip-flop 501 produces signal Qp based on pulse signal PHY sent from self-timer 40 as already described, and sends signal Qp to CLKEN terminal of binary counter 507, inverter 521 and the other terminal of NOR gate 524. Inverters 521-523 delay signal Qp by a predetermined time, and apply it to one of the terminals of NOR gate 524. NOR gate 524 performs logical OR between the output signal of inverter 523 and signal Qp, and inverts results of the logical OR to send the inverted result to inverter 525. Inverter 525 inverts the output signal of NOR gate 524 to apply signal/LATE to each of inverters 502 and 526 and one of the terminals of NAND gate 505 as well as the gate terminal of P-channel MOS transistor 527. Inverter 526 inverts the output signal of inverter 525 to apply signal LATE to the gate terminal of N-channel MOS transistor 528.

Since signal/LATE is produced by the logical OR performed by NOR gate 524 between the signal, which is produced by delaying signal Qp by a predetermined time, and signal Qp, the logical level of signal/LATE does not change in accordance with the timing of rising of the logical level of signal Qp, but changes from H-level to L-level in synchronization with the falling of the logical level of signal Qp. Since signal LATE is the inverted signal of signal/LATE, the logical level of signal LATE changes in accordance with the same timing as signal/LATE.

Inverters 502-504 and 506 as well as NAND gate 505 generate reset signal RST based on signal/LATE in the foregoing manner, and apply reset signal RST to the RESET terminal of binary counter 507. Thus, inverters 502-504 and 506 as well as NAND gate 505 generate reset signal RST by delaying signal/LATE by the delay amount of inverters 502-504. Binary counter 507 counts the components of clock signal CLK sent from the external pin while signal Qp sent from T-type flip-flop 501 is at H-level, and applies count value Q<0:n> to the source terminals of P- and N-channel MOS transistors 527 and 528.

Thereby, P- and N-channel MOS transistors 527 and 528 apply count value Q<0:n>, which is received from binary counter 507, to inverter 529 in accordance with the timing of receiving signal/LATE at L-level and signal LATE at H-level on their gate terminals, respectively. Inverters 529 and 530 latch and hold count value Q<0:n> for a predetermined time. Then, inverters 529 and 530 send count value/QL<0:n> to inverter 531. Inverter 531 inverts count value/QL<0:n> to send count value QL<0:n> to output circuit 190.

As already described, the logical levels of signals LATE and /LATE are switched in synchronization with the falling of the logical level of signal Qp (components LA1, LA2, /LA1, /LA2), and reset signal RST is generated by delaying signal/LATE. Therefore, reset signal RST necessarily has components RST1 and RST2, which are at H-level while signal Qp is at L-level. Thus, reset signal RST attains H-level after the duration of H-level of signal Qp expires. Consequently, binary counter 507 starts the counting of clock signal CLK simultaneously with the change of signal Qp from L-level to H-level, stops the counting of clock signal CLK in synchronization with the change of signal Qp from H-level to L-level, and sends count value Q<0:n> to the source terminals of P- and N-channel MOS transistors 527 and 528. After sending count value Q<0:n> as described above, binary counter 507 receives reset signal RST at H-level, and resets count value Q<0:n>. Therefore, binary counter 507 can perform the counting of clock signal CLK for a duration T5 (or T6) corresponding to the period of pulse signal PHY.

P- and N-channel MOS transistors 527 and 528 are turned on by signals LATE and /LATE to apply count value Q<0:n> to inverter 529, respectively, when binary counter 507 finishes the counting of clock signal CLK and outputs count value Q<0:n>.

According to period measuring circuit 52, as described above, clock signal CLK is counted for a duration corresponding to the period of pulse signal PHY, and count value Q<0:n> is latched by the latch circuit for a predetermined time after the end of counting of clock signal CLK. Then, the count value Q<0:n> is sent to output circuit 190, and count value Q<0:n> is reset. Therefore, clock signal CLK can be counted for the duration corresponding to the period of pulse signal PHY without an influence, which may be exerted by the reset operation of binary counter 507.

The number of inverters for delaying signal Qp by a predetermined time is not restricted to three, and may be generally an odd number. Further, the number of inverters for delaying signal/LATE by a predetermined time is not restricted to three, and may be generally an odd number.

Structures and operations other than the above are the same as those of the first embodiment.

According to the third embodiment, the semiconductor memory device includes the period measuring circuit for performing the count operation to output a count value for the duration corresponding to the period of the pulse signal sent from the timer circuit. Therefore, the period of the pulse signal can be measured more accurately.

[Fourth Embodiment]

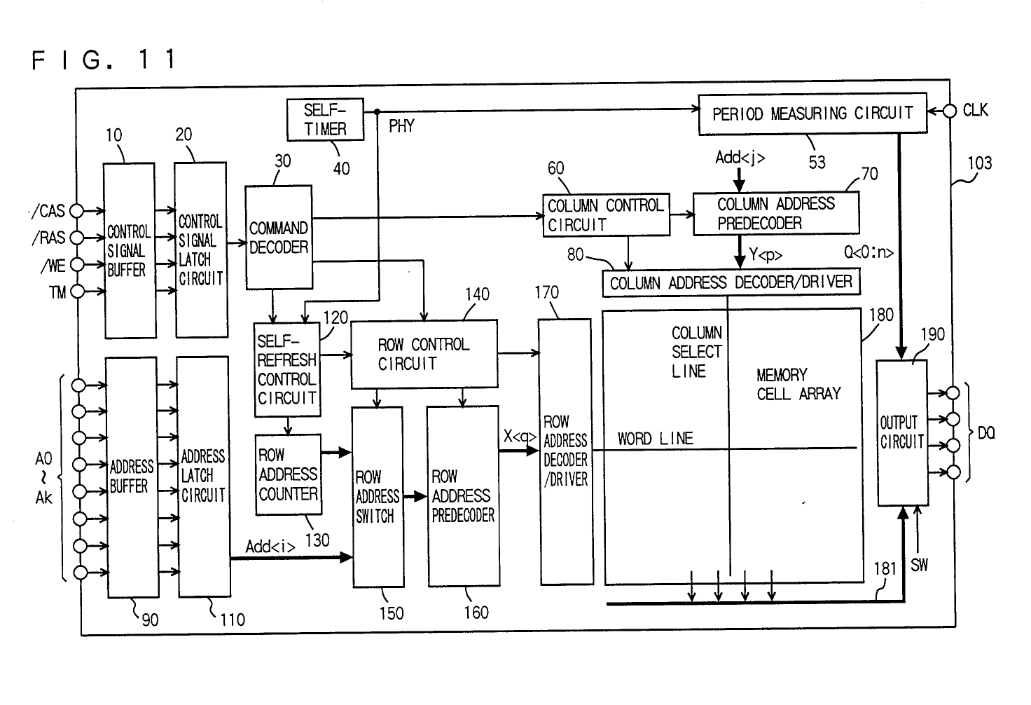

Referring to FIG. 11, a semiconductor memory device 103 of a fourth embodiment is the same as semiconductor memory device 100 except for that a period measuring circuit 53 is employed instead of period measuring circuit 50.

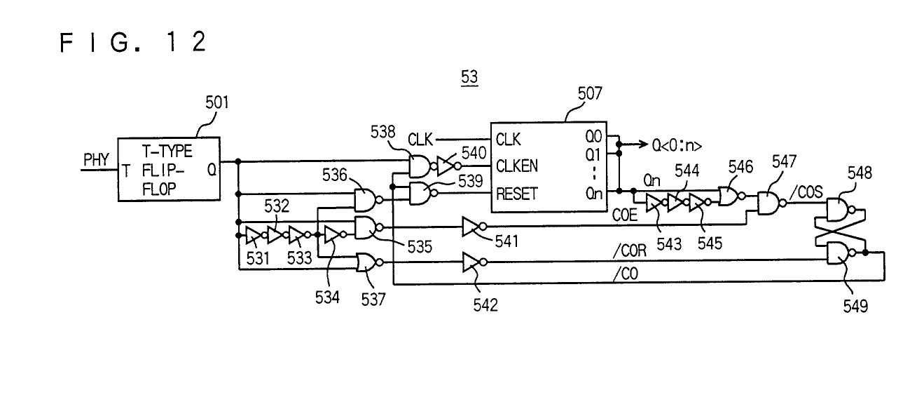

Referring to FIG. 12, period measuring circuit 53 includes T-type flip-flop 501, binary counter 507, inverters 531-534 and 540-545, NAND gates 535, 536, 538, 539 and 547-549, and NOR gates 537 and 546. T-type flip-flop 501 is the same as that already described.

Inverters 531-533 delay signal Qp sent from T-type flip-flop 501 by a predetermined time, and apply the delayed signal to inverter 534 and each of the other terminal of NAND gate 536 and one of the terminals of NOR gate 537. NOR gate 537 performs logical OR between signal Qp delayed by inverters 531-533 and signal Qp sent from T-type flip-flop 501, and inverts results of the logical OR to send the inverted result to inverter 542. Inverter 542 inverts the output signal of NOR gate 537 to apply a signal/COR to the other terminal of NAND gate 549.

Inverter 534 inverts the output signal of inverter 533, and applies it to the other terminal of NAND gate 535. NAND gate 535 performs logical AND between the output signal of inverter 534 and signal Qp sent from T-type flip-flop 501, and inverts results of the logical AND to send the inverted result to inverter 541. Inverter 541 inverts the output signal of NAND gate 535 to apply a signal COE to the other terminal of NAND gate 547.

NAND gate 536 performs logical AND between signal Qp delayed by inverters 531-533 and signal Qp sent from T-type flip-flop 501, and inverts results of the logical AND to send the inverted result to the other terminal of NAND gate 539.

Inverters 543-545 delay a highest bit Qn, which is included in count value Q<0:n> sent from binary counter 507, by a predetermined time, and send it to the other terminal of NOR gate 546. NOR gate 546 performs logical OR between highest bit Qn delayed by inverters 543-545 and highest bit Qn sent from binary counter 507, and inverts results of the logical OR to send the inverted result to one of the terminals of NAND gate 547. NAND gate 547 performs logical AND between the output signal of NOR gate 546 and signal COE sent from inverter 541, inverts results of the logical AND to produce signal/COS, and sends signal/COS to the one of terminals of NAND gate 548.

NAND gates 548 and 549 form a flip-flop, which receives signal/COS sent from NAND gate 547 and signal/COR sent from inverter 542, and issues a signal/CO to the other terminal of NAND gate 538 and the one of terminals of NAND gate 539.

NAND gate 538 performs logical AND between signal Qp sent from T-type flip-flop 501 and signal/CO, and inverts results of the logical AND to send the inverted result to inverter 540. Inverter 540 inverts the output signal of NAND gate 538, and applies it to the CLKEN terminal of binary counter 507. NAND gate 539 performs logical AND between the output signal of NAND gate 536 and signal/CO, inverts results of the logical AND to produce reset signal RST, and applies it to RESET terminal of binary counter 507.

Binary counter 507 counts the components of clock signal CLK sent from the external pin while the signal sent from inverter 540 is at H-level, sends count value Q<0:n> to output circuit 190, and also sends highest bit Qn in count value Q<0:n> to inverters 543 and one of terminals of NOR gate 546. Binary counter 507 resets the count value while reset signal RST sent from NAND gate 539 is at H-level. In this fourth embodiment, clock signal CLK sent from the external pin has a variable frequency. When binary counter 507 receives clock signal CLK having an uncountable frequency, overflow occurs, and binary counter 507 outputs count value Q<0:n>, in which all bits are “0”.

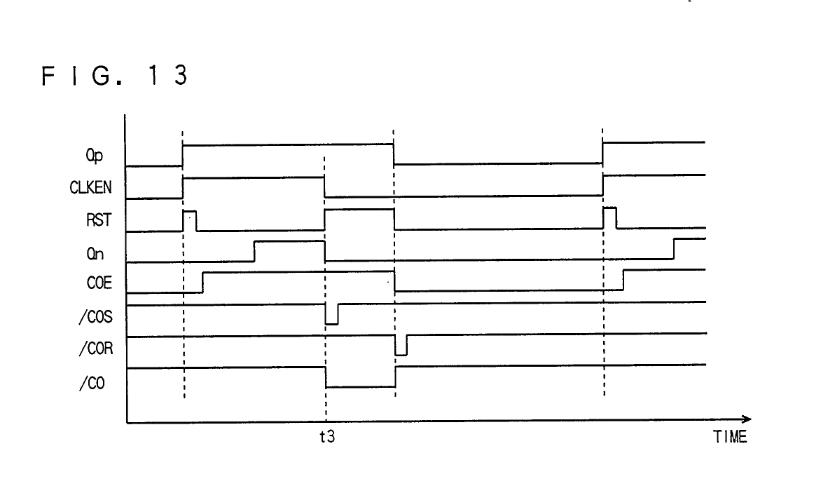

Referring to FIG. 13, description will now be given on operations of period measuring circuit 53. Before starting the counting, binary counter 507 issues count value Q<0:n> entirely formed of bits “0” so that NOR gate 546 issues a signal at L-level, and NAND gate 547 issues signal/COS at H-level independently on the logical level of signal COE. T-type flip-flop 501 issues signal Qp based on pulse signal PHY sent from self-timer 40, and inverters 531-533 delay signal Qp by a predetermined time, and apply it to one of the terminals of NOR gate 537. NOR gate 537 performs logical OR between signal Qp delayed by the predetermined time and signal Qp, and inverts results of the logical OR so that it issues signal COR, which changes from L-level to H-level in synchronization with the falling of logical level of signal Qp. Inverter 542 applies signal/COR, which is prepared by inverting signal COR, to the other terminal of NAND gate 549.

The flip-flop formed of NAND gates 548 and 549 issues signal/CO to the other terminal of NAND gate 538 and the one of terminals of NAND gate 539 based on signals/COS and /COR. In an initial stage of the operations, signals/COS and /COR are at H-level so that the flip-flop formed of NAND gates 548 and 549 issues signal/CO at H-level.

Accordingly, NAND gate 538 outputs a signal corresponding to the logical level of signal Qp, which is sent from T-type flip-flop 501, to inverter 540, and inverter 540 inverts the output signal of NAND gate 538 to apply signal CLKEN to the CLKEN terminal of binary counter 507.

NAND gate 536 performs logical AND between signal Qp sent from T-type flip-flop 501 and signal Qp delayed by inverters 531-533, and inverts results of the logical AND to issue a signal thus inverted to the other terminal of NAND gate 539. NAND gate 539 performs logical AND between the signal sent from NAND gate 536 and signal/CO, and inverts results of the logical AND to issue reset signal RST to the RESET terminal of binary counter 507.

Accordingly, binary counter 507 resets the count value in synchronization with change of signal Qp from L-level to H-level, and starts the counting of component of clock signal CLK (not shown) when reset signal RST changes from H-level to L-level. During the normal counting of clock signal CLK by binary counter 507, highest bit Qn at H-level in count value Q<0:n> is output. When overflow occurs in binary counter 507, highest bit Qn changes from H-level to L-level.

NOR gate 546 performs logical OR between highest bit Qn delayed by a predetermined time and undelayed highest bit Qn, and inverts results of the logical OR. Therefore, the output signal of NOR gate 546 changes from L-level to H-level when the logical level of highest bit Qn changes from H-level to L-level. Since signal COE is produced by logical AND between delayed signal Qp and undelayed signal Qp, signal COE maintains H-level after start of the counting by binary counter 507. Thereby, NAND gate 547 issues signal/COS, of which logical level changes in accordance with the output signal of NOR gate 546 and regardless of the logical level of signal COE. At a time t3, therefore, NAND gate 547 issues signal/COS changing from H-level to L-level. When the delay time provided by inverters 543-545 elapses after highest bit Qn changes from H-level to L-level, NOR gate 546 receives highest bit Qn at L-level and the signal at H-level so that it issues the signal at L-level, and NAND gate 547 issues signal/COS at H-level.

As described above, NAND gate 547 issues signal/COS changing from H-level to L-level in accordance with the overflow in binary counter 507 at time t3. Therefore, inverters 543-545, NOR gate 546 and NAND gate 547 form an overflow detecting circuit for detecting the overflow in binary counter 507.

Signal/COR is produced by the logical OR between signal Qp, which is delayed by three inverters 531-533, and undelayed signal Qp. Therefore, signal/COR maintains H-level until the logical level of signal Qp changes from H-level to L-level. Thereby, the flip-flop formed of NAND gates 548 and 549 issues signal/CO, which changes from H-level to L-level at time t3, to NAND gates 538 and 539. NAND gate 538 issues a signal at H-level based on signal/CO at L-level and signal Qp at H-level, and inverter 540 issues a signal at L-level to the CLKEN terminal of binary counter 507. NAND gate 539 issues reset signal RST at H-level to the RESET terminal of binary counter 507 based on signal/CO at L-level. Thereby, binary counter 507 stops the counting.

As described above, period measuring circuit 53 of the fourth embodiment stops the count operation and resets the count value when overflow occurs in binary counter 507.

In the fourth embodiment, clock signal CLK is sent from the external pin to semiconductor memory device 103 after changing its frequency to a higher frequency. When the frequency of clock signal CLK increases, overflow occurs in binary counter 507, and the count operation stops as already described. Thereby, binary counter 507 issues count value Q<0:n> entirely formed of bits at L-level to I/O terminal DQ via output circuit 190 so that a tester, i.e., a person performing the test of semiconductor memory device 103 can determine the frequency of clock signal CLK causing the overflow.

Since the tester of semiconductor memory device 103 has already known the changed frequency of clock signal CLK, the highest frequency within a range not causing the overflow is sent to semiconductor memory device 103 for measuring the period of pulse signal PHY. As described above, clock signal CLK of a high frequency is sent to semiconductor memory device 103. This is because the higher frequency reduces the period of clock signal CLK, and can reduce a length of unit for measuring the period of pulse signal PHY so that the accuracy of the period measurement can be improved.

Structures and operations other than the above are the same as those of the first embodiment.

According to the fourth embodiment, the semiconductor memory device includes the period measuring circuit, which stops the count operation when overflow occurs. Therefore, the frequency of the clock signal, which causes the overflow in the count operation, can be easily determined. Consequently, the period of the pulse signal can be accurately determined by using the clock signal having the highest frequency in the frequency range not causing the overflow in the count operation.

[Fifth Embodiment]

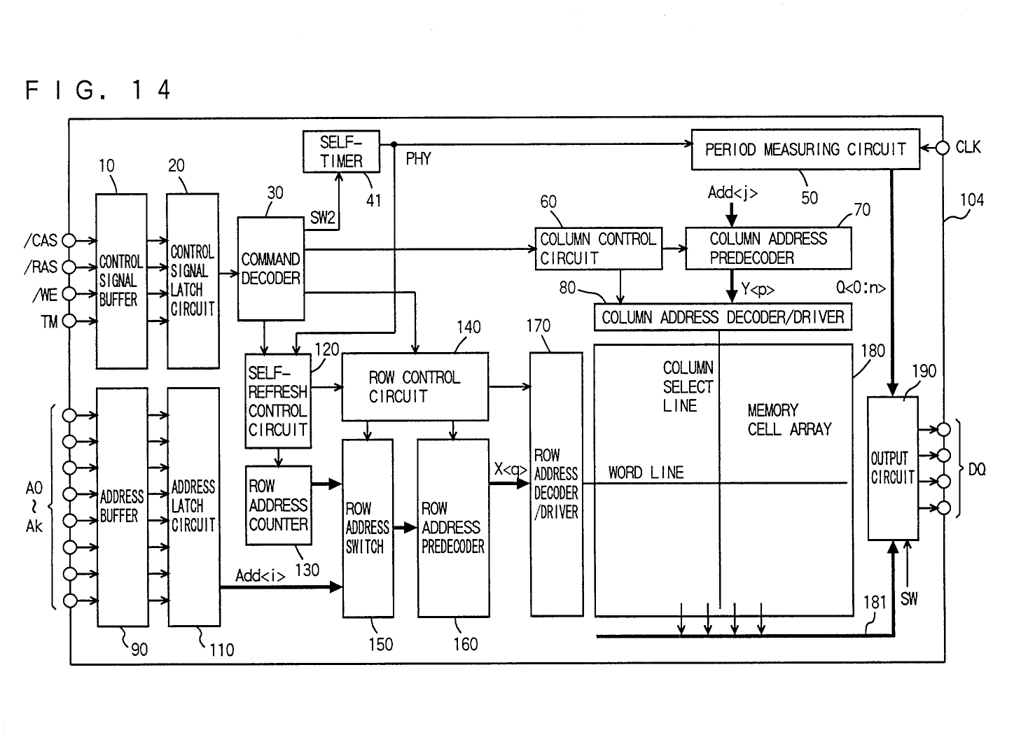

Referring to FIG. 14, a semiconductor memory device 104 according to a fifth embodiment is the same as semiconductor memory device 100 except for that a self-timer 41 is employed instead of self-timer 40 in semiconductor memory device 100. In semiconductor memory device 104, command decoder 30 applies a switch signal SW1 to output circuit 190, and applies a switch signal SW2 to self-timer 41.

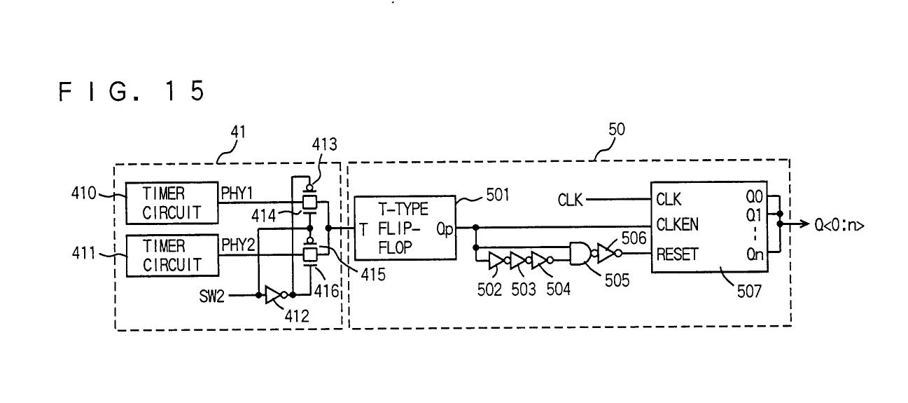

Referring to FIG. 15, self-timer 41 includes timer circuits 410 and 411, an inverter 412, P-channel MOS transistors 413 and 415, and N-channel MOS transistors 414 and 416.

Timer circuit 410 issues a pulse signal PHY1 to P- and N-channel MOS transistors 413 and 414. Timer circuit 411 produces a pulse signal PHY2 having a period different from a period of pulse signal PHY1, and applies it to P- and N-channel MOS transistors 415 and 416.

Inverter 412 receives switch signal SW2 from command decoder 30, inverts received switch signal SW2 and applies the inverted signal to gate terminals of P- and N-channel MOS transistors 413 and 416.

P-channel MOS transistor 413 has a source terminal connected to a source terminal of N-channel MOS transistor 414, and also has a drain terminal connected to a drain terminal of N-channel MOS transistor 414. N-channel MOS transistor 414 receives switch signal SW2 from command decoder 30 on its gate terminal. P- and N-channel MOS transistors 413 and 414 form a transfer gate, which applies pulse signal PHY1 sent from timer circuit 410 to T-type flip-flop 501 of period measuring circuit 50 when self-timer 41 receives switch signal SW2 at H-level from command decoder 30.

P-channel MOS transistor 415 has a source terminal connected to a source terminal of N-channel MOS transistor 416, and also has a drain terminal connected to a drain terminal of N-channel MOS transistor 416. P-channel MOS transistor 415 receives switch signal SW2 from command decoder 30 on its gate terminal. P- and N-channel MOS transistors 415 and 416 form a transfer gate, which applies pulse signal PHY2 sent from timer circuit 411 to T-type flip-flop 501 of period measuring circuit 50 when self-timer 41 receives switch signal SW2 at L-level from command decoder 30.

In the fifth embodiment, as described above, self-timer 41 selectively applies two periodic signals having different periods to period measuring circuit 50. Period measuring circuit 50 measures the period of pulse signal PHY1 or PHY2 sent from self-timer 41 in accordance with the foregoing operations.

Timer circuit 410 produces pulse signal PHY1 forming a reference. Therefore, period measuring circuit 50 selectively measures the periods of pulse signals PHY1 and PHY2, and applies the measured period to I/O terminal DQ via output circuit 190. Thereby, the period of pulse signal PHY2 sent from timer circuit 411 can be tuned so that the measured period of pulse signal PHY2 may match with the measured period of pulse signal PHY1.

In the structure described above, self-timer 41 includes two timer circuits. This is not restrictive, and three or more timer circuits may be generally employed for issuing a plurality of periodic signals having different periods.

Semiconductor memory device 104 may employ any one of period measuring circuits 51-53 already described instead of period measuring circuit 50.

Structures and operations other than the above are the same as those of the first embodiment.

According to the fifth embodiment, the semiconductor memory device includes a self-timer for selectively issuing a plurality of periodic signals having different periods, and the period measuring circuit for measuring the period of the periodic signal sent from the self-timer. Therefore, one of the periodic signals can be determined as the basic periodic signal, and the other periodic signal(s) can be tuned to have the period(s) matching with the period of the basic periodic signal.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor memory device for performing input/output of data into and from memory cells in synchronization with a reference periodic signal, and performing a refresh operation for said memory cells in synchronization with a periodic signal, comprising:
a plurality of memory cells;
a periodic signal generating circuit generating said periodic signal;
a peripheral circuit performing the input/output of said data into and from each of said plurality of memory cells in synchronization with said reference periodic signal, and performing said refresh operation in synchronization with said periodic signal sent from said periodic signal generating circuit; and
a period measuring circuit measuring the period of said periodic signal by using said reference periodic signal having a second period shorter than a first period of said periodic signal.

2. The semiconductor memory device according to claim 1, further comprising:
an I/O terminal; and
an output circuit outputting the period of said periodic signal measured by said period measuring circuit to said I/O terminal.

3. The semiconductor memory device according to claim 1, wherein
said period measuring circuit measures the period of said periodic signal by counting the number of components of said reference periodic signal existing between two neighboring components of said periodic signal.

4. The semiconductor memory device according to claim 3, wherein
said period measuring circuit includes:
a detection signal producing circuit producing, based on said periodic signal sent from said periodic signal generating circuit, a detection window signal used for detecting the number of the components of said reference periodic signal existing between the two neighboring components of said periodic signal, and
a counter circuit counting said components in response to said detection window signal and outputting results of the count.

5. The semiconductor memory device according to claim 3, wherein
said period measuring circuit removes an influence exerted by a reset operation of resetting results of said component counting when said period measuring circuit counts said components.

6. The semiconductor memory device according to claim 5, wherein
said period measuring circuit fills up a period of said reset operation to count said components.

7. The semiconductor memory device according to claim 6, wherein
said period measuring circuit includes:
a first detection signal producing circuit producing a preliminary detection window signal having an amplitude width corresponding to the period of said periodic signal in synchronization with said periodic signal sent from said periodic signal generating circuit,
a reset signal generating circuit generating a reset signal having a predetermined amplitude width and synchronized with rising of a logical level of said preliminary detection window signal,
a second detection signal producing circuit producing a detection window signal having an amplitude width equal to a sum of the amplitude width of said preliminary detection window signal and the amplitude width of said reset signal and synchronized with rising of the logical level of said preliminary detection window signal, and
a counter circuit counting said components in response to said detection window signal, outputting results of the counting and resetting said results of the counting in response to said reset signal.

8. The semiconductor memory device according to claim 5, wherein
said period measuring circuit performs said reset operation while said components are not being counted.

9. The semiconductor memory device according to claim 8, wherein
said period measuring circuit includes:
a counter circuit counting said components,
a holding circuit holding results of the counting of said counter circuit for a predetermined duration and outputting the results of the counting, and
a rest signal generating circuit generating a reset signal for resetting said counter circuit after output of said count results from said counter circuit, and sending said reset signal to said counter circuit.

10. The semiconductor memory device according to claim 9, wherein
said period measuring circuit further includes:
a detection signal producing circuit producing, based on said periodic signal sent from said periodic signal generating circuit, a detection window signal used for detecting the number of the components of said reference periodic signal existing between the two neighboring components of said periodic signal,
a gate circuit receiving said count results from said counter circuit, and sending the received count results to said holding circuit, and
a gate signal producing circuit producing a gate signal for opening said gate circuit in synchronization with ending of said component count operation by said counter circuit, wherein
said counter circuit counts said components in response to said detection window signal, and
said gate circuit outputs said count results to said holding circuit in synchronization with said gate signal.

11. The semiconductor memory device according to claim 3, wherein
said period measuring circuit counts said components, using the reference periodic signal having a frequency smaller than a frequency of said reference periodic signal causing overflow in the component count operation.

12. The semiconductor memory device according to claim 11, wherein
said period measuring circuit outputs as said count results a value equal to a reset value when the overflow occurs in said count operation.

13. The semiconductor memory device according to claim 12, wherein
said period measuring circuit includes:
a counter circuit counting said components,
an overflow detecting circuit detecting the overflow in said count operation, and
a reset signal generating circuit generating a reset signal for resetting said counter circuit and sending the produced reset signal to said counter circuit, in response to an overflow detection signal sent from said overflow detecting circuit.

14. The semiconductor memory device according to claim 13, wherein
said counter circuit outputs said count results formed of n (n: natural number) bits, and
said overflow detecting circuit outputs said overflow detection signal when transition of the logical level of the highest bit among said n bits from a first logical level to a second logical level is detected.

15. The semiconductor memory device according to claim 14, further comprising:
an I/O terminal, and
an output circuit outputting said count results sent from said counter circuit to said I/O terminal.

16. The semiconductor memory device according to claim 1, wherein
said periodic signal generating circuit selectively issues to said period measuring circuit a first periodic signal having a first period and a second periodic signal having a second period different from said first period.

17. The semiconductor memory device according to claim 16, wherein
said periodic signal generating circuit includes:
a first generating circuit generating said first periodic signal,
a second generating circuit generating said second periodic signal, and
a gate circuit selectively outputting said first and second periodic signals.

18. The semiconductor memory device according to claim 17, wherein
the period of said second periodic signal is tuned based on the period of said first periodic signal measured by said period measuring circuit.
